(19) United States
(12) Patent Application Publication
(10) Pub. No.: US 2022/0406952 A1
(43) Pub. Date: Dec. 22, 2022

(54) Longpass Distributed Bragg Reflector (LPDBR)

(71) Applicants: Stephen Polly, Rochester, NY (US); Julia D'Rozario, Rochester, NY (US); George Nelson, Champaign, IL (US); Seth Hubbard, Pittsford, NY (US)

(72) Inventors: Stephen Polly, Rochester, NY (US); Julia D'Rozario, Rochester, NY (US); George Nelson, Champaign, IL (US); Seth Hubbard, Pittsford, NY (US)

(73) Assignee: Rochester Institute of Technology, Rochester, NY (US)

(21) Appl. No.: 17/807,549

(22) Filed: Jun. 17, 2022

Related U.S. Application Data
(60) Provisional application No. 63/211,824, filed on Jun. 17, 2021.

(51) Int. Cl. H01L 31/0687; H01L 31/056; H01L 31/054; H01L 31/0693; H01L 31/18

(52) U.S. Cl. CPC H01L 31/06875; H01L 31/056; H01L 31/0547; H01L 31/0693; H01L 31/184

(57) ABSTRACT

A reflector including a substrate and a plurality of alternating layers of two materials having different indices of refraction disposed on the substrate, wherein the reflector exhibits a central peak in reflectance vs wavelength and the reflectance of the high-energy side-lobes is increased in intensity and the reflectance of the low-energy side-lobes is reduced in intensity and method for making the reflector is disclosed.

### CROSS REFERENCE

This application claims the benefit of the filing date of U.S. Provisional Patent Application Ser. No. 63/211,824, filed Jun. 17, 2021, which is hereby incorporated by reference in its entirety.

This invention was made with government support under grant number FA9453-19-C-0592 awarded by Dept. of Defense, Dept. of the Air Force, Material Command. The government has certain rights in the invention.

### FIELD

The disclosure relates to a reflector including a substrate and a plurality of alternating layers of two materials having different indices of refraction disposed on the substrate, wherein the reflector exhibits a central peak in reflectance versus wavelength and the reflectance of the high-energy side-lobes is increased in intensity and the reflectance of the low-energy side-lobes is reduced in intensity, methods for making the reflector, and a solar cell comprising the reflector.

### BACKGROUND

A solar cell converts light from the sun into electricity. First, photons are absorbed, which create electron-hole pairs, and are subsequently separated and minority carriers are collected by an internal electric field (p/n diode). This generates an electrical current, which is extracted at a voltage depending on material parameters of the absorber and the potential drop across the previously described electric field, as power. This power can perform work on an external circuit or be stored in e.g., a battery. In semiconductors such as GaAs, there is a limit to the energy (color) of photons that can be absorbed and contribute to the overall power conversion efficiency, based on the fundamental band gap of the material and the wavelength dependent absorption coefficient. Photons with energy lower than the band gap will transmit through the device and not contribute to current generation. Photons with energy higher than the band gap will be absorbed with a probability based on the total thickness of the absorber material and the absorption coefficient. Generally, high energy photons (blue) require a thinner total thickness for complete absorption, versus lower energy photons (red) which require thicker absorber material.

Typically, solar cells are made “optically thick,” meaning the physical thickness of the absorber is sufficient to collect the majority of total energy available from the solar spectrum, up to the band gap energy. This allows the solar cell to maximize current generation and total power conversion efficiency. However, there can be a limit here to thickness. A generated minority carrier absorbed at the very back of a thick solar cell must survive long enough to diffuse to the electric field at the junction for collection. This survival time is called minority carrier lifetime, and the characteristic length it can travel is described as the minority carrier diffusion length. If the minority carrier does not make it to the junction, it will recombine and give off light or heat, reducing the efficiency of solar energy collection in the device.

In harsh environments such as space, radiation causes damage in the semiconductor, reducing the minority carrier diffusion length over time, causing the solar cell efficiency to degrade as the radiation dose increases. A solution to this is to reduce the thickness of the semiconductor, reducing the length any minority carrier would need to travel. This can significantly improve the expected lifetime of a device under a particular radiation dose but has the negative side effect of reducing the total thickness of optical absorber. This reduces the light absorbed, therefore the current generated, and reduces the overall efficiency. By integrating an epitaxial reflector structure below the thinned junction, some of that “lost” light can be reflected back into the solar cell where it has another chance for absorption. This increases the optical path length in the device while keeping the physical thickness lowered.

A typical integrated epitaxial reflector is a distributed Bragg reflector, made from alternating layers of two materials with differing indices of refraction. This structure creates an internal reflection similar to that shown in FIG. 6, with a central high-reflectance peak bounded by lower intensity side-lobe reflections at both higher and lower energy from the central peak. The thickness of each material is fixed, based on the design of the central reflectance peak and width, which are repeated in pairs several times. As more pairs are added, a higher percentage reflectance is achieved, increasing the number of photons able to be reflected towards the thinned solar cell for improved collection. This design allows a thinned solar cell to have both improved radiation tolerance while not losing efficiency.

Typically, in space photovoltaics where the highest efficiency devices are in demand, multiple junctions made from different materials with different absorption properties are stacked together to make the most use of the spectrum of light from the sun. In a specific case such as an In_{0.49}Ga_{0.51}P/GaAs/In_{0.3}Ga_{0.7}As solar cell, the InGaP will collect light in the 300 nm to 650 nm range, GaAs from 650 to 870 nm, and InGaAs from 870 to 1240 nm. If the middle GaAs junction is thinned, and a DBR placed below it with a reflectance peak designed near the GaAs band gap at 870 nm, the low-energy side-lobe reflections will reflect low energy light back towards the sun and away from the bottom junction where those photons could have been absorbed and contributed to overall device performance. Thus, there must be a careful balance to the DBR design and placement to maximize improving performance in the GaAs device while not too severely negatively affecting the performance of the bottom InGaAs device.

Conventional matched pair DBRs have been previously used for this application. Published work has used multiple thinner DBRs with different matched thicknesses each to widen the central reflectance peak. There are also methods of grading the material composition from one material to the other for e.g., laser cavity applications. However, the function of a conventional DBR is typically thought of as linked to matched pairs of fixed thicknesses (tied to constituent material's optical constants) to cause constructive and destructive interference with light resulting in the characteristic reflectance curve shown in FIG. 6. The art lacks a change that ignores conventional wisdom and allows a change in the structure of the device to achieve a more efficient specific result.

### SUMMARY

One aspect of the present disclosure relates to a reflector. The reflector includes a substrate. A plurality of alternating layers of a first material having a first index of refraction and a second material having a second index of refraction are disposed on the substrate. The first index of refraction is different from the second index of refraction. A thickness of at least one layer of the first material in the plurality of alternating layers is not the same as other layers of the first material in the plurality of alternating layers. A thickness of at least one layer of the second material in the plurality of alternating layers is not the same as other layers of the second material in the plurality of alternating layers. The reflector is configured to provide a central peak in reflectance versus wavelength. The reflectance of high-energy side-lobes is increased in intensity and the reflectance of low-energy side-lobes is reduced in intensity as compared to a reflector wherein the thickness of each layer of the first material of the plurality of alternating layers is the same and the thickness of each layer of the second material of the plurality of alternating layers is the same.

Another aspect of the present disclosure relates to a method for making a reflector. The method includes disposing a single layer of a first material on a substrate. A reflectance is calculated. A layer of a second material is placed on the first layer. A reflectance is calculated. The thickness of each layer is optimized to reduce a merit function. A second layer of the first material is disposed on the layer of the second material. The thicknesses of each layer are re-optimized. Layers are added until either a target condition of the merit function is reached, or a sum of the thickness of all layers is reached.

A further aspect of the present disclosure relates to a method for making a reflector. A fixed thickness is chosen as the quarter-wave optical thickness at the chosen central peak wavelength for each of two materials. A model is constructed with a chosen total number of alternating layers of the two materials disposed on a substrate. Reflection is calculated. Changes in the layer thicknesses are simulated, either individually or of multiple layers at a time to reduce the merit function until a threshold is reached.

Another aspect of the present disclosure relates to a solar cell device. The solar cell device includes a first solar cell and a second solar cell. A reflector is disposed between the first solar cell and the second solar cell. The reflector includes a plurality of alternating layers of a first material having a first index of refraction and a second material having a second index of refraction are disposed on the substrate. The first index of refraction is different from the second index of refraction. A thickness of at least one layer of the first material in the plurality of alternating layers is not the same as other layers of the first material in the plurality of alternating layers. A thickness of at least one layer of the second material in the plurality of alternating layers is not the same as other layers of the second material in the plurality of alternating layers. The reflector is configured to provide a central peak in reflectance versus wavelength. The reflectance of high-energy side-lobes is increased in intensity and the reflectance of low-energy side-lobes is reduced in intensity as compared to a reflector wherein the thickness of each layer of the first material of the plurality of alternating layers is the same and the thickness of each layer of the second material of the plurality of alternating layers is the same.

These and other aspects of the present disclosure will become apparent upon a review of the following detailed description and the claims appended thereto.

### BRIEF DESCRIPTION OF THE DRAWINGS

FIG. 1 is a generic example structure of a Long Pass Distributed Bragg reflector (LPDBR) composed of Layers 1 through n. shown with cladding (or superstrate/substrate) on the top and bottom surface. Material A and B have different indices of refraction and some or all layers may have different but specific thicknesses corresponding to desired device performance metrics;

FIG. 2 is a specific example structure (use case) of LPDBR composed of layers 1 through 67 alternating between p-doped InAlP and InGaP. Shown with cladding on the top by a GaAs solar cell, and on the bottom with a tunnel junction, metamorphic grade, and InGaAs solar cell. Each layer of the LPDBR has different, but specific, thicknesses corresponding to desired device performance metrics;

FIG. 3 shows specific thicknesses of each layer of an example of a LPDBR;

FIG. 4 is a modeled reflectance of a (˜5 μm total thickness) LPDBR showing high energy side-lobe oscillations (600 nm to 870 nm) a central reflectance peak (870 nm to 940 nm) and quenched low-energy side lobe oscillations (940 nm to 1300 nm);

FIG. 5 is a comparison/overlap of FIG. 4 and FIG. 6 comparing LPDBR (solid) and conventional DBR (dashed);

FIG. 6 is a modeled reflectance of a (˜5 μm total thickness) conventional DBR using 33 pairs of alternating layers of 78.1 nm InAlP and 71.7 nm InGaP and a final layer of 78.1 nm InAlP; and

FIG. 7 is a LPDBR “13×” pair layer structure with 27 total layers designed for experimental validation.

### DETAILED DESCRIPTION

A reflector; a method for fabricating a reflector; and a solar cell containing a reflector are disclosed.

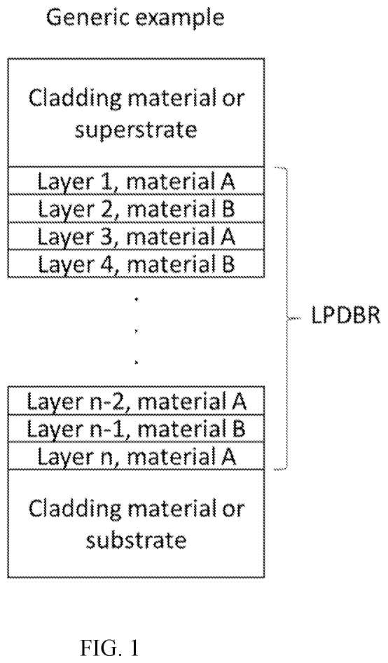

In an embodiment, a reflector includes a substrate and a plurality of alternating layers of two materials disposed on the substrate. Each one of the two materials has a different indices of refraction. FIG. 1 is a generic example structure of a Long Pass Distributed Bragg reflector (LPDBR) of the present disclosure composed of Layers 1 through n. shown with cladding (or superstrate/substrate) on the top and bottom surface. Material A and B have different indices of refraction and some or all layers may have different but specific thicknesses corresponding to desired device performance metrics. The thickness of each layer of the first material of the plurality of alternating layers is not the same. For example, at least one layer of the first material may have a thickness that is different from the other layers. In another example, a subset of the layers of the first material may have varying thicknesses. In yet another example, each of the layers of the first material has a different thickness. The thickness of each layer of the second material of the plurality of alternating layers is not the same. For example, at least one layer of the second material may have a thickness that is different from the other layers. In another example, a subset of the layers of the second material may have varying thicknesses. In yet another example, each of the layers of the second material has a different thickness. The reflector exhibits a central peak in reflectance versus wavelength, wherein the reflectance of the high-energy side-lobes is increased in intensity and the reflectance of the low-energy side-lobes are reduced in intensity as compared to the same reflector except wherein the thickness of each layer of the first material of the plurality of alternating layers the same and the thickness of each layer of the second material of the plurality of alternating layers the same.

Suitable substrates include materials that can be grown epitaxially between crystals, such as III-V materials (AlGaIn/AsPSb combinations) and III-N materials (AlGaIn/N); semiconductor materials such as C, Si, Ge, Sn, as well as binary, ternary, or higher combinations of the same (e.g., SiₓGe₁₋ₓ, SiC) and the like; semiconductor materials such as the binaries GaAs, InAs, AlAs, GaP, InP, AlP, GaSb, InSb, GaN, InN, AlN, as well as ternary, quaternary, or higher combinations of the same (e.g. AlₓGa₁₋ₓAs, In_{y}Ga_{1-y}N) and the like; oxides or nitrides such as SiOx, Al₂O₃, SiNx, and the like; common optical coating materials such as ZnS and MgF₂, and the like; polymers such as polyimide, polycarbonate, silicone, and the like; materials with varying porosity to affect their refractive index such as silicon and porous silicon, and the like; materials with different construction to affect their refractive index such as crystalline silicon and amorphous silicon, and the like. The reflector may be disposed on top of a substrate, on the bottom of a substrate, or between two substrates which may be the same or different materials. The reflector may be enclosed on the sides by additional substrate material, or left open to air, or encapsulated with some other material as required for an application. The substrate may be flat, convex, or concave.

In an embodiment, a reflector is a planar structure having a plurality of alternating layers of two different materials with respect to indices of refraction, and the alternating layers of varying thickness, deposited either between other materials or on a surface of a substrate, wherein the structure exhibits a peak in reflectance vs wavelength, the height of which is related to the total number of layers, the width of the peak is related to the difference in index of refraction between the two materials, and the central peak location is related to the thickness of the layers and has high-energy side-lobes increased in intensity with respect to what would be expected from conventional designs, while the low-energy side lobes are decreased in intensity or quenched with respect to what would be expected from conventional designs, and wherein the structure is highly transparent in the higher wavelengths after the central reflectance peak, while maintaining high reflectivity of the central reflectance peak and higher-energy side-lobe reflections.

The planar structure includes a plurality of alternating layers of two materials with different indices of refraction. Any two materials (e.g., M1, M2) with different indices of refraction can be used in the reflector. Suitable materials include materials that can be grown epitaxially between crystals, such as III-V materials (AlGaIn/AsPSb combinations) and III-N materials (AlGaIn/N); semiconductor materials such as C, Si, Ge, Sn, as well as binary, ternary, or higher combinations of the same (e.g., SiₓGe₁₋ₓ, SiC) and the like; semiconductor materials such as the binaries GaAs, InAs, AlAs, GaP, InP, AlP, GaSb, InSb, GaN, InN, AlN, as well as ternary, quaternary, or higher combinations of the same (e.g. AlₓGa₁₋ₓAs, In_{y}Ga_{1-y}N) and the like; oxides or nitrides such as SiOx, Al₂O₃, SiNx, and the like; common optical coating materials such as ZnS and MgF₂, and the like; polymers such as polyimide, polycarbonate, silicone, and the like; materials with varying porosity to affect their refractive index such as silicon and porous silicon, and the like; materials with different construction to affect their refractive index such as crystalline silicon and amorphous silicon, and the like. There must be a difference between the index of the two materials (relative to each other), and the layers of material must alternate. The minimum difference between the refractive index of the two materials must be greater than zero. There is no prescribed maximum difference in refractive index (apart from physical limitations of design requirements for regions of high and low reflectance), though practical considerations for materials and applications will preferably limit this difference to less than 10. In the use cases disclosed below the difference is less than 0.5.

In the present device, each layer of the alternating layers is not the same thickness, but rather the thickness of the layers can vary. Some or all of the alternating layers can have different thicknesses. For example, the present reflector is in contrast to a conventional Distributed Bragg Reflector (DBR), where the alternating material (e.g., M1, M2) layers are of fixed thickness throughout the structure. E.g., in a DBR every odd numbered layer is M1 and every even numbered layer is M2, and all odd layers are the same thickness T1 and all even layers are the same thickness T2, wherein T1 and T2 are different. The reflector of the present disclosure provides increased reflectance intensity of high-energy side-lobes and decreased reflectance intensity of low-energy side-lobes compared to a conventional DBR.

In an embodiment, the prescribed thickness is ¼ of the optical thickness (a.k.a., “quarter wave optical thickness” or QWOT) of a specific wavelength of light within each material as modified by that material's index of refraction. The specific wavelength chosen defines the center of the main reflectance peak. In this invention, the thicknesses of the material layers are different from each other throughout the reflector to achieve the desired optical properties. The thickest any individual layer will be approximately the QWOT of that material for the designated main reflectance peak. The thinnest any individual layer will be is likely on the order of 10 nm or less depending on the design requirements and manufacturing capability.

The material layers are deposited either between other materials or on a surface of a planar structure. Thus, the layers can be deposited on a surface, which can be integrated within other materials/devices. Suitable techniques include deposition by metalorganic vapor phase epitaxy (MOVPE) a.k.a., metalorganic chemical vapor deposition (MOCVD) or organometallic vapor phase epitaxy (OMVPE). The materials could also be deposited by molecular beam epitaxy (MBE), possibly also by hydride vapor phase epitaxy (HVPE). This structure can benefit from the high quality III-V crystalline materials grown by these methods, for the particular application of integrating between electrically active optoelectronic devices. When integrating into other types of structures, or electrically disconnected devices, a LPDBR could be made from a variety of optical materials spanning glass, MgF₂, ZnS, oxides, and the like, which could be deposited by various thin film deposition including thermal evaporation, electron beam evaporation, sputtering, atomic layer deposition, chemical vapor deposition (low pressure, or plasma-enhanced), and the like.

The structure exhibits a peak in reflectance vs wavelength. This is the central peak and is defined by alternating layers of differing index of refraction each with a QWOT of the wavelength desired for the “peak”.

The total reflectance of the peak is related to the total number of layers used. As more layer pairs (pairs of high and low index of refraction) are added, the reflective effects are superimposed and the reflective effect is increased.

The width of the peak is related to the difference in index of refraction between the two materials used. The width is related to the difference in refractive index and to a degree the number of pairs.

The central peak location is related to the thickness of the layers.

In accordance with an embodiment, the high-energy side-lobes are increased in intensity with respect to what would be expected from conventional designs. Varying the thicknesses of the alternating index layers allows the side-lobe reflections at the high-energy side of the central peak to have increased reflectivity. The low-energy side lobes are quenched. By varying the thicknesses of the alternating index layers the side-lobe reflections at the low-energy side of the central peak are decreased in reflectivity.

The structure can be highly transparent at wavelengths after the central reflectance peak. The low reflectivity on the low-energy side means light is not reflected back towards the source. As long as the materials have a low absorbance/extinction coefficient at wavelengths beyond the central peak, the structure remains highly transparent in this range.

The structure maintains high reflectivity of the central reflectance peak and higher-energy side-lobe reflections. Thus, the reflector of the present invention compared with a prior art reflector having approximately the same volume of material in each but having different thickness designs will have nearly identical central peak performance, with the invention having enhanced high-energy side-lobe reflections as well as reduced low-energy side-lobe reflections which can allow high transparency in the low-energy region.

In accordance with an embodiment, the effects of increasing the number of layers on the central peak also affect the side lobes. As more high/low index layer pairs are added, the greater the effect of increasing the high-energy reflectance and reducing the low-energy reflectance. However, the addition of more layer pairs is not trivial, each structure must be designed independently. For example, a reflector designed with 14 layers will have different layer thicknesses than a reflector designed with 20 layers.

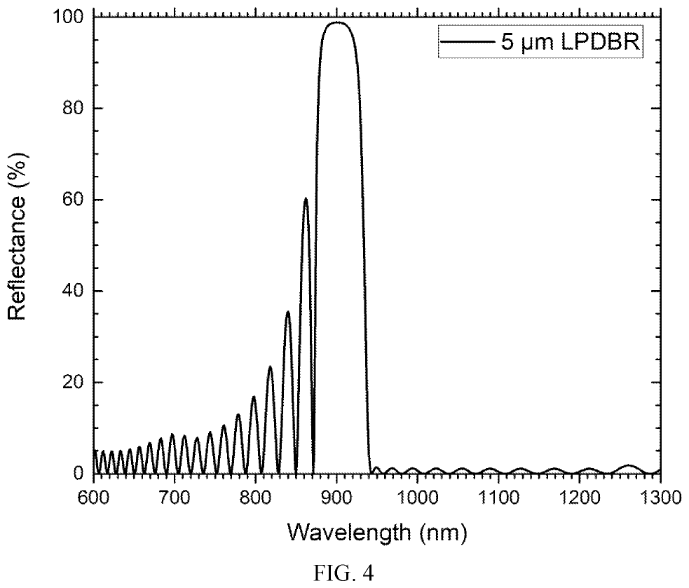

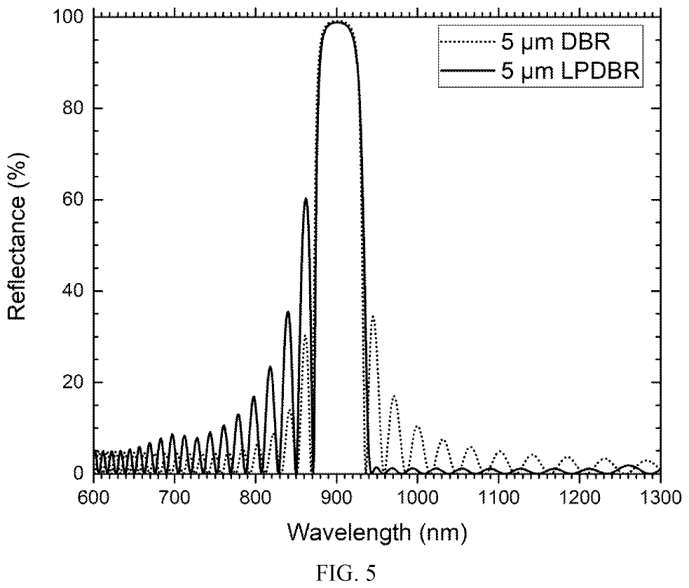

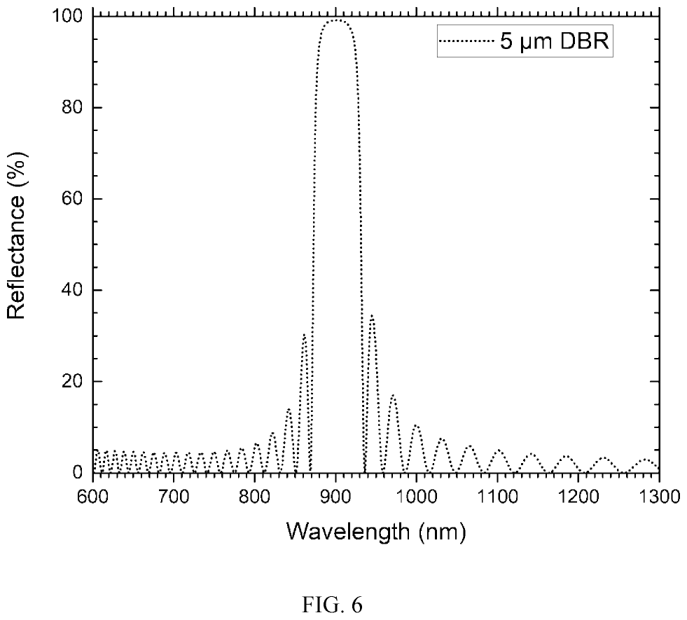

In an embodiment the present structure exhibits a peak in reflectance vs wavelength, the height of which is related to the total number of layers used, the width of the peak related to the difference in index of refraction between the two materials used, and the central peak location related to the thicknesses of the layers. The present invention differs from a DBR in the side-lobe reflections. A DBR has side-lobe reflections at higher and lower energies than the central reflectance peak (FIG. 6). In the present invention, the high-energy side-lobes are increased in intensity, while the low-energy side-lobes are quenched (FIG. 4). FIG. 5 illustrates the difference between reflectance vs wavelength for the prior art DBR and the reflector of the present disclosure. The present disclosure provides a structure that is highly transparent at wavelengths after the central reflectance peak, while maintaining high reflectivity of the central reflectance peak and at the wavelengths in the higher-energy side-lobe reflections.

While not being bound to any theory, this result is believed to be accomplished by specific variation in thicknesses of the component layers, as opposed to a traditional DBR which repeats the same layer pair of thicknesses throughout the structure.

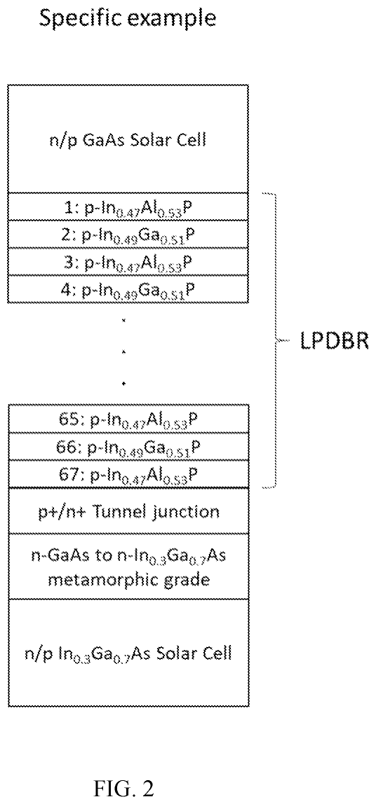

The reflector can be designed in two ways, a “bottom up” method or a “lateral” method. Both methods utilize computer assisted optimization of reflectance as calculated by a transfer matrix method (TMM) optical calculation to determine destructive and constructive reflective interference as a function of wavelength, wavelength dependent index of refraction, and individual film thickness. First, a single central peak wavelength is chosen where maximum reflectivity is desired (e.g., in the example provided in FIGS. 2-4, target reflectivity is equal to 100% at 900 nm). Second, a spectral range is chosen where low reflectivity (and high transmission, if absorbance in the materials is low) is desired (e.g., in the example provided in FIGS. 2-4, target reflectivity is equal to 0% from 950 nm to 1250 nm). For optimal performance, the low reflectivity region is chosen to start beyond the edge of the central reflectance peak (e.g., in the example provided in FIGS. 2-4, the central reflectance peak span approximately 870 nm to 940 nm). The width of the central reflectance peak is dependent on the difference in index of refraction of the two materials used to create the reflector, as well as the total number of layers used. The width of the central peak may be calculated beginning with the “lateral” method.

Both methods utilize a merit function which determines the average wavelength dependent sum squared difference between the prescribed reflectance targets described above and the calculated reflectance from the TMM model. Each target (i.e. high reflectance at a specific wavelength, and low reflectance across a specific wavelength range) is given equal weight in this merit function.

In the “lateral” method a fixed thickness is chosen for each material, chosen as the quarter-wave optical thickness (QWOT) at the chosen central peak wavelength. A model is constructed with a chosen total number of alternating layers of the two materials disposed on a substrate or between substrates and reflection is calculated. The computer program then iterates changing layer thicknesses, either individually or of multiple layers at a time, to minimize the merit function until a threshold is reached as determined by either design constraints, computational time constraints, or a tolerance constraint.

In the “bottom up” method a single layer of a first material is disposed on a substrate or between substrates and reflectance is calculated with the TMM model. A layer of a second material is placed on the first layer and thicknesses of each layer are optimized to minimize the merit function. A second layer of the first material is placed on the prior layer and all layers are re-optimized. This process continues until either the target condition of the merit function is reached, or a sum of the thickness or total number of all layers is reached.

In addition to applications in photovoltaics, the reflector of the present invention could be used in any optical or optoelectronic device or component that requires a highly reflective component at higher energy and a highly transparent component at lower energy. This could include single or multi-color light emitting diodes, single or multi-color lasers, photodetectors, protective optical coatings/filters (optical components, personal protective equipment).

The reflector of the present invention could be used as an epitaxial reflector in a single or multijunction solar cell, allowing the solar cell active material to be thinned enabling both improved radiation tolerance and to maintain high beginning of life performance/efficiency.

The reflector of the present invention could be used in a multijunction solar cell to reduce the physical thickness of one or more than one junction, while maintaining high optical power collection in that thinned junction, simultaneously limiting parasitic reflective loss for lower junction(s).

The reflector of the present invention could be used in a single-wavelength light emitting diode structure to allow transmission of photons very close to the emitted wavelength, including similar applications for laser diodes.

The reflector of the present invention could be used in a multi-wavelength light emitting diode to allow high reflection of a higher energy top photon emitter while transmitting a lower energy bottom photon emitter, including similar applications for laser diodes.

The reflector of the present invention could be used as an optical filter to reflect strongly at a specific wavelength and pass at a longer wavelength very close to the reflected wavelength. A specific use case beyond what is normal with a traditional long-pass filter.

The reflector of the present invention could be used in a DataCell combining a solar cell with an optical modulator and retroreflector to improve performance of a PV device and prevent insertion loss.

The disclosure will be further illustrated with reference to the following specific examples. It is understood that these examples are given by way of illustration and are not meant to limit the disclosure or the claims to follow.

### EXAMPLES

### Example 1

A general example of a reflector of the present disclosure is shown in FIG. 1. For example: other material compositions of InₓGa₁₋ₓP and Al_{y}In_{1-y}P could be used. Other materials entirely could be used (e.g., GaP/AlP; AlₓGa₁₋ₓAs/Al_{y}Ga_{1-y}As), they could be binary, ternary, quaternary etc. Materials may be grown lattice matched to the substrate but lattice matching to the substrate is not required. Materials could be grown strained or strain-balanced. Growth by MOVPE is not required, could be e.g., molecular beam epitaxy (MBE) or some other method. If no subsequent epitaxial material is required, more constraints are lifted. The invented structure could be made from dielectric materials (e.g., ZnS/MgF₂) or metal oxides (e.g., Al₂O₃/TiO₂) deposited using other thin-film techniques like e-beam evaporation or sputtering. It could be made from transparent organic material such as polymers.

### Example 2

In an InGaP/GaAs/InGaAs triple junction solar cell destined for a high-radiation environment such as space, it is desirable to thin the GaAs junction to reduce the effects of radiation exposure/damage over time. Doing so reduces the volume of light absorbing material, reducing overall device efficiency. Incorporating a conventional DBR below this device, with the central DBR reflecting peak near the band edge, allows recovery of optical path length through the device, restoring efficiency lost by physically thinning the absorber. The conventional DBR introduces long-wavelength (sub-GaAs bandgap) reflection oscillations, which parasitically reflect light away from the bottom InGaAs junction, where it could be absorbed. This reduces the bottom cell efficiency. Replacing the conventional DBR with a Longpass Distributed Bragg Reflector (LPDBR) provides the benefits of improved optical path length in the middle junction from the high reflectance of the central peak, while reducing the parasitic reflective losses in the bottom cell.

A specific example of this reflector is shown in FIG. 2. The LPDBR is identified between the top GaAs solar cell and bottom InGaAs solar cell, including necessary tunnel junction and metamorphic grade, for this particular application. If the LPDBR region was removed, and the GaAs solar cell directly connected to the tunnel junction, the result would be a typical commercially manufactured structure.

The structure was made from alternating layers of In_{0.49}Ga_{0.51}P and Al_{0.47}In_{0.53}P lattice matched to GaAs and grown epitaxially by a metalorganic vapor phase epitaxy tool (MOVPE, a.k.a. metalorganic chemical vapor deposition: MOCVD) manufactured by AIXTRON. Growth occurs on single crystal GaAs substrates (Wafer Technology Ltd.). Reagents are all commercially available and include trimethylgallium (Dockweiler Chemicals), trimethylindium (EMD Performance Materials), trimethylaluminum (EMD Performance Materials), and phosphine (Matheson). Materials are grown lattice-matched to the GaAs substrate at 650° C. at low pressure (100 mbar) in a hydrogen ambient. Layer thicknesses are selected based on design for LPDBR central peak wavelength.

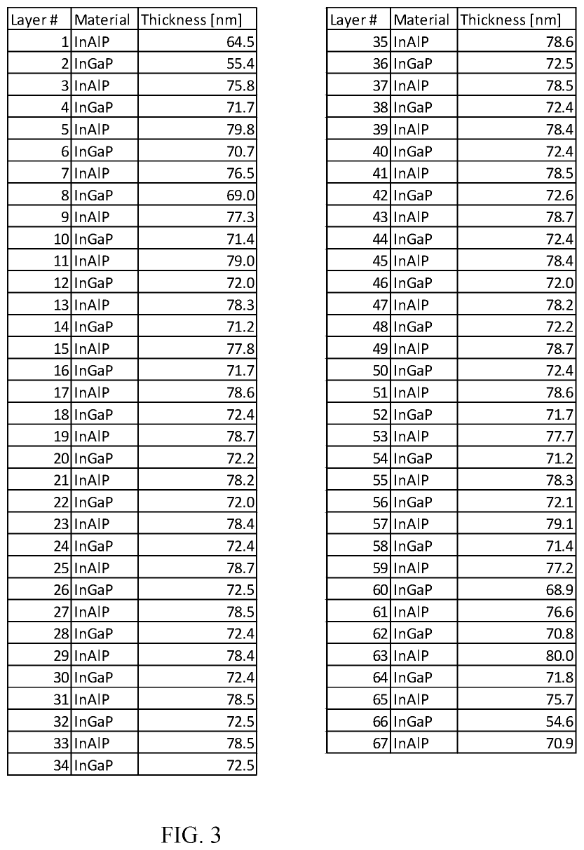

In this specific example, the reflector consists of 67 layers, alternating between In_{0.47}Al_{0.53}P (InAlP) and In_{0.49}Ga_{0.51}P (InGaP). These layers have different indices of refraction. The specific layer thicknesses are shown in FIG. 3.

### Example 3

A modeled reflectance between the tunnel junction/metamorphic grade/bottom junction and the GaAs junction is shown in FIG. 4. This is contrasted with a conventional DBR made with similar design parameters (e.g., peak reflectance wavelength, total thickness), which uses fixed thicknesses for each material, duplicated in pairs throughout the structure. The conventional DBR reflectance is shown in FIG. 6. The LPDBR and conventional DBR are compared directly in FIG. 5. The LPDBR shows high energy side-lobe oscillations (600 nm to 870 nm) a central reflectance peak (870 nm to 940 nm) and quenched low-energy side lobe oscillations (940 nm to 1300 nm).

This example is a preferred form for the particular use-case described. The specifics of individual layer thicknesses can be changed to target different peak wavelengths, depending on the specific application. The more layers are added, the higher the peak reflectance percentage, and the more the low-energy oscillations can be suppressed. Alternatively, the invention can be designed for less layers and a thinner overall structure at the tradeoff of lower performance.

The reflector of the present disclosure allows each layer to have a specific thickness to suppress reflections on the low-energy side of the main reflectance peak, as shown in FIG. 4 (with a comparison between a conventional DBR and LPDBR in FIG. 5). Using a LPDBR, the central reflectance peak can be maximized and set right against the GaAs band gap, and very little parasitic reflective loss to the bottom cell will occur. This can be seen specifically in the lower reflectance in the solid LPDBR plot, compared to the dashed conventional DBR plot, in FIG. 5. These two devices were designed under similar constraints of peak percentage reflectance, peak wavelength, and total overall thickness.

While providing similar main-peak reflectance to a conventional DBR, the inventive device exhibits reduced low-energy side-lobe reflection oscillation amplitude. This reduction is beneficial to overall device performance, as any reflections here are parasitic to the performance to any lower junction(s). The inventive device also exhibits increased high-energy side lobe reflection oscillation amplitude. This increase is beneficial to overall device performance, as any non-absorbed photons in this range will be reflected back into the intended junction for improved collection probability, improving device performance.

### Example 4

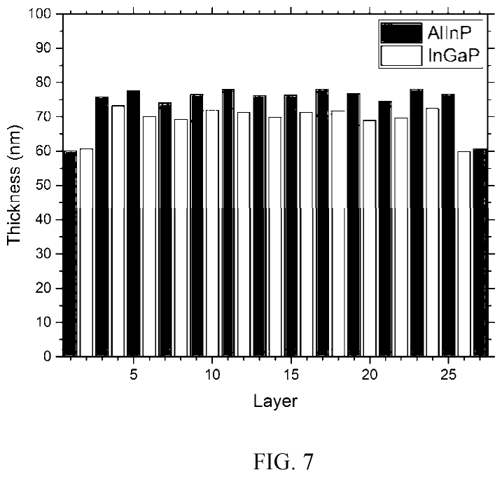

A device design of a LPDBR “13×” pair structure with 27 layers is shown in FIG. 7.

Although various embodiments have been depicted and described in detail herein, it will be apparent to those skilled in the relevant art that various modifications, additions, substitutions, and the like can be made without departing from the spirit of the disclosure and these are therefore considered to be within the scope of the disclosure as defined in the claims which follow.

What is claimed:

1. A reflector, comprising:
a substrate; and
a plurality of alternating layers of a first material having a first index of refraction and a second material having a second index of refraction disposed on the substrate, wherein the first index of refraction is different from the second index of refraction, wherein a thickness of at least one layer of the first material in the plurality of alternating layers is not the same as other layers of the first material in the plurality of alternating layers, wherein a thickness of at least one layer of the second material in the plurality of alternating layers is not the same as other layers of the second material in the plurality of alternating layers, wherein the reflector is configured to provide a central peak in reflectance versus wavelength, wherein the reflectance of high-energy side-lobes is increased in intensity and the reflectance of low-energy side-lobes is reduced in intensity as compared to a reflector wherein the thickness of each layer of the first material of the plurality of alternating layers is the same and the thickness of each layer of the second material of the plurality of alternating layers is the same.

2. The reflector of claim 1, wherein the reflector is disposed on a top surface of the substrate or on a bottom surface of the substrate.

3. The reflector of claim 1, wherein the reflector is disposed between a pair of substrates.

4. The reflector of claim 1, wherein the first material is InAlP and the second material is InGaP.

5. The reflector of claim 1, wherein a subset of the layers of the first material in the plurality of alternating layers have varying thicknesses.

6. The reflector of claim 5, wherein each of the layers of the first material in the plurality of alternating layers have a different thickness.

7. The reflector of claim 1, wherein a subset of the layers of the second material in the plurality of alternating layers have varying thicknesses.

8. The reflector of claim 7, wherein each of the layers of the second material in the plurality of alternating layers have a different thickness.

9. The reflector of claim 1, wherein the thickness of the first material and the second material is about the quarter wave optical thickness of a specific wavelength of light within each material as modified by the index of refraction for each material.

10. The reflector of claim 9, wherein the specific wavelength defines a center of the main reflectance peak for the reflector.

11. The reflector of claim 9, wherein the thicknesses of the alternating layers range between the quarter wave optical thickness of that material for the main reflectance peak and approximately 10 nm or less.

12. A method for making a reflector, comprising:
disposing a single layer of a first material on a substrate;
calculating a reflectance;
placing a layer of a second material on the first layer;
calculating a reflectance;
optimizing the thicknesses of each layer to reduce a merit function;
placing a second layer of the first material on the layer of the second material;
re-optimizing the thicknesses of each layer;
continuing to add layers until either a target condition of the merit function is reached, or a sum of the thickness of all layers is reached.

13. A method for making a reflector, comprising:
choosing a fixed thickness as the quarter-wave optical thickness at the chosen central peak wavelength for each of two materials;
constructing a model with a chosen total number of alternating layers of the two materials disposed on a substrate;
calculating reflection; and
simulating changes in the layer thicknesses, either individually or of multiple layers at a time to reduce the merit function until a threshold is reached.

14. A solar cell device comprising:
a first solar cell;
a second solar cell; and
a reflector disposed between the first solar cell and the second solar cell, the reflector comprising a plurality of alternating layers of a first material having a first index of refraction and a second material having a second index of refraction disposed on the substrate, wherein the first index of refraction is different from the second index of refraction, wherein a thickness of at least one layer of the first material in the plurality of alternating layers is not the same as other layers of the first material in the plurality of alternating layers, wherein a thickness of at least one layer of the second material in the plurality of alternating layers is not the same as other layers of the second material in the plurality of alternating layers, wherein the reflector is configured to provide a central peak in reflectance versus wavelength, wherein the reflectance of high-energy side-lobes is increased in intensity and the reflectance of low-energy side-lobes is reduced in intensity as compared to a reflector wherein the thickness of each layer of the first material of the plurality of alternating layers is the same and the thickness of each layer of the second material of the plurality of alternating layers is the same.

15. The solar cell device of claim 14, wherein the first solar cell is a GaAs solar cell.

16. The solar cell device of claim 14, wherein the second solar cell is an InGaAs solar cell.

17. The solar cell device of claim 14 further comprising:
a tunnel junction and a metamorphic grade located between the reflector and the second solar cell.
